(19) United States
(12) Patent Application Publication
(10) Pub. No.: US 2019/0148654 A1
(43) Pub. Date: May 16, 2019

(54) DISPLAY UNIT AND METHOD OF MANUFACTURING DISPLAY UNIT

(71) Applicant: JOLED INC., Tokyo (JP)

(72) Inventors: Eiji HASEGAWA, Tokyo (JP); Yuichiro ISHIYAMA, Tokyo (JP)

(21) Appl. No.: 16/185,156

(22) Filed: Nov. 9, 2018

(30) Foreign Application Priority Data
Nov. 13, 2017 (JP) 2017-218246

(51) Int. Cl. H01L 51/00; H01L 27/32; H01L 51/52; H01L 51/56; B32B 15/08; B32B 15/18; B32B 27/08; B32B 27/36

(52) U.S. Cl. CPC H01L 51/0097; H01L 27/3244; H01L 51/5253; H01L 51/56; B32B 15/08; B32B 2457/206; B32B 27/08; B32B 27/36; H01L 51/0004; B32B 2255/20; B32B 15/18

(57) ABSTRACT

A display unit includes a flexible substrate, a thin film transistor layer, a display element layer, an electrically conductive member, and a protective member. The flexible substrate includes a first surface and a second surface that face each other. The thin film transistor layer is provided over the first surface of the flexible substrate. The display element layer includes a light-emitting layer, and is provided over the first surface of the flexible substrate, with the thin film transistor layer interposed between the display element and the flexible substrate. The electrically conductive member is provided to be in contact with the second surface of the flexible substrate. The protective member faces the second surface of the flexible substrate, with the electrically conductive member interposed between the protective member and the flexible substrate.

### CROSS REFERENCE TO RELATED APPLICATIONS

This application claims the benefit of Japanese Priority Patent Application JP 2017-218246 filed on Nov. 13, 2017, the entire contents of which are incorporated herein by reference.

### BACKGROUND

The technology relates to a display unit using a flexible substrate, and a method of manufacturing the display unit.

There has been proposed a display unit using a flexible substrate such as a plastic substrate (e.g., a resin substrate). For example, reference is made to Japanese Unexamined Patent Application Publication No. 2014-49441. The display unit includes, on the flexible substrate, a thin film transistor (TFT) layer and a display element layer such as an organic electroluminescence (EL) element, for example.

### SUMMARY

It has been desired to stabilize characteristics of a thin film transistor layer in a display unit.

It is desirable to provide a display unit that makes it possible to stabilize characteristics of a thin film transistor layer, and a method of manufacturing the display unit.

A display unit according to an embodiment of the technology includes a flexible substrate, a thin film transistor layer, a display element layer, an electrically conductive member, and a protective member. The flexible substrate includes a first surface and a second surface that face each other. The thin film transistor layer is provided over the first surface of the flexible substrate. The display element layer includes a light-emitting layer, and is provided over the first surface of the flexible substrate, with the thin film transistor layer interposed between the display element and the flexible substrate. The electrically conductive member is provided to be in contact with the second surface of the flexible substrate. The protective member faces the second surface of the flexible substrate, with the electrically conductive member interposed between the protective member and the flexible substrate.

A method of manufacturing a display unit according to an embodiment of the technology includes: joining a support substrate to a second surface of a flexible substrate including a first surface and the second surface that face each other; forming a thin film transistor layer over the first surface of the flexible substrate; forming, over the thin film transistor layer, a display element layer including a light-emitting layer; detaching the support substrate from the second surface of the flexible substrate, and forming an electrically conductive member that is in contact with the second surface of the flexible substrate; and joining a protective member to the second surface of the flexible substrate, with the electrically conductive member interposed between the protective member and the flexible substrate.

### BRIEF DESCRIPTION OF THE DRAWINGS

The accompanying drawings are included to provide a further understanding of the technology, and are incorporated in and constitute a part of this specification. The drawings illustrate example embodiments and, together with the specification, serve to explain the principles of the technology.

FIG. 1 is a schematic cross-sectional view of an example outline configuration of a display unit according to one embodiment of the technology.

FIG. 2 is a schematic cross-sectional view of the display unit illustrating one process of a method of manufacturing the display unit illustrated in FIG. 1.

FIG. 3 is a schematic cross-sectional view of the display unit illustrating a process subsequent to FIG. 2.

FIG. 4 is a schematic cross-sectional view of the display unit illustrating a process subsequent to FIG. 3.

FIG. 5 is a schematic cross-sectional view of the display unit illustrating a process subsequent to FIG. 4.

FIG. 6 is a schematic cross-sectional view of the display unit illustrating one process of a method of manufacturing a display unit according to a comparative example.

FIG. 7 is a schematic cross-sectional view of the display unit illustrating a process subsequent to FIG. 6.

FIG. 8 illustrates a threshold voltage of a thin film transistor in each of the processes illustrated in FIGS. 6 and 7.

FIG. 9 is a block diagram illustrating an example outline configuration of the display unit illustrated in FIG. 1.

FIG. 10 is a block diagram illustrating an example outline configuration of an electronic apparatus including the display unit illustrated in FIG. 9.

### DETAILED DESCRIPTION

In the following, some example embodiments of the technology are described in detail with reference to the accompanying drawings. Note that the following description is directed to illustrative examples of the technology and not to be construed as limiting to the technology. Factors including, without limitation, numerical values, shapes, materials, components, positions of the components, and how the components are coupled to each other are illustrative only and not to be construed as limiting to the technology. Further, elements in the following example embodiments which are not recited in a most-generic independent claim of the technology are optional and may be provided on an as-needed basis. The drawings are schematic and are not intended to be drawn to scale. Note that the like elements are denoted with the same reference numerals, and any redundant description thereof will not be described in detail.

### Example Embodiment

### Configuration

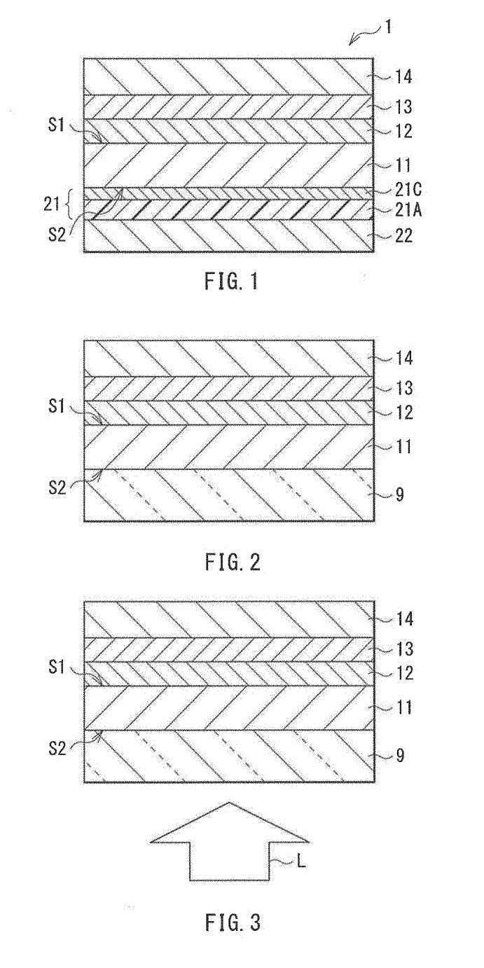

FIG. 1 is a schematic cross-sectional view of an example outline configuration of a display unit (i.e., a display unit 1) according to an embodiment of the technology. The display unit 1 may be, for example, a flexible display including an organic electroluminescence (EL) element over a flexible substrate 11, for example. The flexible substrate 11 includes a surface (i.e., a first surface S1) and a back surface (i.e., a second surface S2) that face each other. The display unit 1 may include, over the first surface S1 of the flexible substrate 11, for example, a thin film transistor (TFT) layer 12, a display element layer 13, and a protective layer 14, in this order. The display unit 1 includes, adjacent to the second surface S2 of the flexible substrate 11, a protective member 22 with an adhesive layer 21 interposed therebetween.

The flexible substrate 11 may be configured, for example, by a resin material such as polyethylene terephthalate (PET), polyimide (PI), polycarbonate (PC), polyethylene naphthalate (PEN), polyamide (PA), and polyether sulfone (PES). That is, the flexible substrate 11 may be configured, for example, by a resin substrate (e.g., a plastic substrate). However, a constituent material of the flexible substrate 11 is not limited to such a resin material; any other material may be used to configure the flexible substrate 11. The flexible substrate 11 may have a thickness of 5 μm to 100 μm, for example.

The TFT layer 12 provided over the first surface S1 of the flexible substrate 11 may include a thin film transistor, for example. The thin film transistor may be, for example, a top-gate, a bottom-gate, or a dual-gate thin film transistor, and may include a semiconductor layer in a selective region over the flexible substrate 11. The semiconductor layer may include a channel region (i.e., an active layer). The semiconductor layer may be configured by an oxide semiconductor that contains, as a main component, an oxide of one or more elements of indium (In), gallium (Ga), zinc (Zn), tin (Sr), titanium (Ti), and niobium (Nb), for example. Specific but non-limiting examples of the oxide semiconductor may include indium-tin-zinc oxide (ITZO), indium-gallium-zinc oxide (IGZO: InGaZnO), zinc oxide (ZnO), indium-zinc oxide (IZO), indium -gallium oxide (IGO), indium-tin oxide (ITO), and indium oxide (InO). Note that the semiconductor layer may be configured by a material such as low-temperature polycrystalline silicon (LTPS) and amorphous silicon (a-Si).

The display element layer 13 is provided over the first surface S1 of the flexible substrate 11, with the TFT layer 12 interposed therebetween. The display element layer 13 may include a plurality of pixels and a display element (e.g., a light-emitting element). The display element may be driven by a backplane to perform display. A plurality of thin film transistors may be disposed on the backplane. Non-limiting examples of the display element may include an organic EL element and a liquid crystal display element. Among these, the organic EL element may include, from side of the TFT layer 12, an anode electrode, an organic electroluminescent layer, and a cathode electrode, for example. The anode electrode may be coupled, for example, to a source-drain electrode in the above-described thin film transistor. The cathode electrode may receive a cathode electric potential common to each of pixels through a wiring line, for example. The organic EL element may include, between the anode electrode and the organic electroluminescent layer, a hole injection layer and a hole transport layer in this order from side of the anode electrode. The organic EL element may include, between the cathode electrode and the organic electroluminescent layer, an electron injection layer and an electron transport layer in this order from side of the cathode electrode.

The protective layer 14 that covers the display element layer 13 may protect the display element layer 13 from the outside. The protective layer 14 may be configured, for example, by an inorganic material such as silicon oxide (SiOₓ), silicon nitride (SiNₓ), silicon oxynitride (SiON), and aluminum oxide (AlO). The protective layer 14 may be configured by an organic material. The protective layer 14 may have a stacked structure of an organic material film and an inorganic material film.

The adhesive layer 21 provided between the flexible substrate 11 (the second surface S2) and the protective member 22 may adhere the flexible substrate 11 and the protective member 22 together. In the present example embodiment, the adhesive layer 21 may include an electrically conductive member 21C that is in contact with the second surface S2 of the flexible substrate 11. This suppresses generation of static electricity upon joining the protective member 22 to the second surface S2 of the flexible substrate 11 although the detail is described later.

The electrically conductive member 21C may be, for example, carbon (C), i.e., so-called soot, generated through carbonization of a portion of the flexible substrate 11. In an example embodiment, the electrically conductive member 21C may be provided uniformly on an entire surface of the second surface S2 of the flexible substrate 11. The electrically conductive member 21C may have a thickness that is smaller than a thickness of the adhesive layer 21. For example, the electrically conductive ember 21C may have a thickness of 20 μm or smaller. The thickness of the electrically conductive member 21C may be defined by size of a soot particle (i.e., aggregate), for example.

The adhesive layer 21 may include an adhesive 21A in addition to the electrically conductive member 21C. The adhesive 21A may be provided to fill a gap between the electrically conductive member 21C and the protective member 22. The adhesive 21A may be configured, for example, by a resin material such as an acrylic resin material. The adhesive layer 21 may have a thickness of 3 μm to 50 μm, for example. In an example embodiment, a resistivity of a facing surface (i.e. an adhesive surface), of the adhesive layer 21 including the electrically conductive member 21C, with respect to the flexible substrate 11 may be 10⁵ Ω/sq or lower. The resistivity of the facing surface, of the adhesive layer 21, with respect to the flexible substrate 11 may be 1 Ω/sq to 10³ Ω/sq, for example.

The protective member 22 may face the second surface S2 of the flexible substrate 11, with the adhesive layer 2.1 interposed therebetween. The protective member 22 may be adhered to the second surface S2 of the flexible substrate 11 by the adhesive layer 21. The protective member 22 may protect and reinforce the flexible substrate 11. The protective member may be configured, for example, by a thin film of metal such as stainless steel or a resin material such as polyethylene terephthalate (PET). The protective member 22 may have a thickness of 5 μm to 100 μm, for example.

### Manufacturing Method

The above-described display unit 1 may be manufactured, for example, as follows, as illustrated in FIGS. 2 to 5.

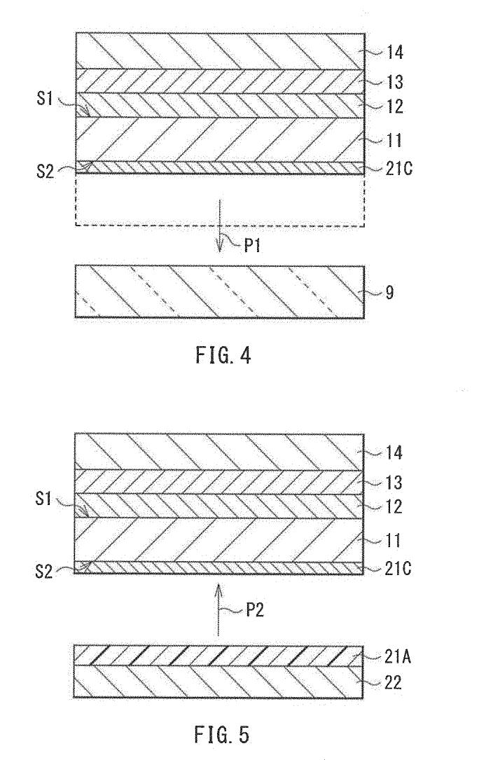

As illustrated in FIG. 2, a support substrate 9 is first joined to the second surface S2 of the flexible substrate 11. The support substrate 9 may suppress, for example, warping of the flexible substrate 11 upon formation of the TFT layer 12 and the display element layer 13 over the first surface S1 of the flexible substrate 11. The support substrate 9 is detached from the flexible substrate 11 in a subsequent process, as illustrated in FIG. 4 described later. The support substrate 9 may be configured by glass, for example. Non-limiting examples of the glass may include quartz glass, soda glass, and non-alkali glass.

Non-limiting examples of the method of joining the flexible substrate 11 and the support substrate 9 together may include application of varnish, etc. onto the support substrate 9 and baking, and joining using an adhesive, etc. Non-limiting examples of a constituent material of the adhesive may include siloxane.

Next, after joining of such a support substrate 9, there may be formed the TFT layer 12, the display element layer 13, and the protective layer 14 in this order over the first surface S1 of the flexible substrate 11.

In a specific but non-limiting example, a semiconductor layer made of the above-described material (e.g., the oxide semiconductor) may be first formed over the flexible substrate 11 using a sputtering method, for example. Thereafter, photolithography or etching, for example, may be used to pattern the semiconductor layer into a predetermined shape. Further, various insulating films or electrodes may be formed, thereby allowing for formation of the TFT layer 12.

Subsequently, the display element layer 13 is formed over the TFT layer 12. For example, in a case where the display element layer 13 includes the organic EL element, for example, the display element layer 13 that includes, for example, the anode electrode, the hole injection layer, the hole transport layer, the organic electroluminescent layer, the electron transport layer, the electron injection layer, and the cathode electrode may be formed over the TFT layer 12. In an example embodiment, the organic electroluminescent layer may be formed using a printing method. Upon the formation of the organic electroluminescent layer using the printing method, baking may be performed at a temperature of 200° C. or higher. Accordingly, even when irradiation energy of laser light L is increased upon irradiation of the laser light L in a subsequent process (as illustrated in FIG. 3), the organic electroluminescent layer is less likely to be detached as compared with an organic electroluminescent layer formed using a vapor-deposition method.

Thereafter, the protective layer 14 made of the above-described material may be formed over the display element layer 13 using a chemical vapor deposition (CVD) method, for example.

After the formation of the protective layer 14, the laser light L may be irradiated from side of the support substrate 9, for example, as illustrated in FIG. 3. Subsequently, as illustrated in FIG. 4, the support substrate 9 is detached from the flexible substrate 11 (as indicated by an arrow P1). One conceivable reason for the detachment of the support substrate 9 from the flexible substrate 11 by means of such irradiation of the laser light L lies in the following mechanism. When the laser light L is irradiated, for example, bonding force among atoms or molecules that constitute the flexible substrate 11 may be lost or attenuated. Otherwise bonding force among atoms or molecules, in a substance, that constitute the above-described adhesive may be lost or attenuated. This may possibly cause occurrence of interlayer detachment or interface detachment, thus leading to the detachment of the support substrate 9.

In the present example embodiment, the irradiation of the laser light L may carbonize a portion of the flexible substrate 11 on side of the second surface S2. Accordingly, when the support substrate 9 is detached, the electrically conductive member 21C in contact with the second surface S2 of the flexible substrate 11 has been formed. In a more specific but non-limiting example, a portion of the resin material that constitutes the flexible substrate 11 may be sublimated by the irradiation of the laser light L. The sublimation of the resin material may cause generation of electrically conductive carbon (i.e., the electrically conductive member 21C). In an example embodiment, the irradiation energy of the laser light L may be 1.15 times or higher than energy necessary for the detachment of the support substrate 9. By irradiating the laser light L having larger energy than the energy necessary for the detachment of the support substrate 9, carbon serving as the electrically conductive member 21C is more likely to be generated. For example, when the laser light L that is an excimer laser having a wavelength of 308 nm is irradiated, an energy density necessary for the detachment of the support substrate 9 may be about 200 mJ/cm², and thus the laser light L having an energy density of about 230 mJ/cm² to about 260 mJ/cm² may be irradiated in an example embodiment.

After the formation of the electrically conductive member 21C that is in contact with the second surface S2 of the flexible substrate 11, as illustrated in FIG. 5, the protective member 22 may be joined to the electrically conductive member 21C with the adhesive 21A interposed therebetween (as indicated by an arrow P2). In the present example embodiment, the electrically conductive member 21C may be formed to be in contact with the second surface S2 of the flexible substrate 11, thus suppressing the generation of static electricity upon the joining of the protective member 22.

As described above, the display unit 1 illustrated in FIG. 1 may be manufactured.

### Workings and Effects

### Basic Operation

In the display unit 1, on the basis of an image signal to be inputted from an external device, each of pixels in the display element layer 13 may be driven to perform display, thus allowing for image display. At this occasion, the TFT layer 12 may involve driving of the thin film transistor in response to a voltage for each of the pixels, for example. In a specific but non-limiting example, when a voltage equal to or higher than a threshold voltage is supplied to the thin film transistor, the above-described semiconductor layer may be activated, (i.e., a channel may be formed). As a result, an electric current may be flowed between a pair of source-drain electrodes in the thin film transistor. The display unit 1 may thus perform the image display by utilizing the voltage driving performed on the thin film transistor.

In the display unit 1 of the present example embodiment, the electrically conductive member 21C is provided to be in contact with the second surface S2 of the flexible substrate 11, thus making it possible to suppress the generation of static electricity upon the joining of the protective member 22 (as illustrated in FIG. 5). Description is given below of the workings and effects with reference to a comparative example.

### Comparative Example

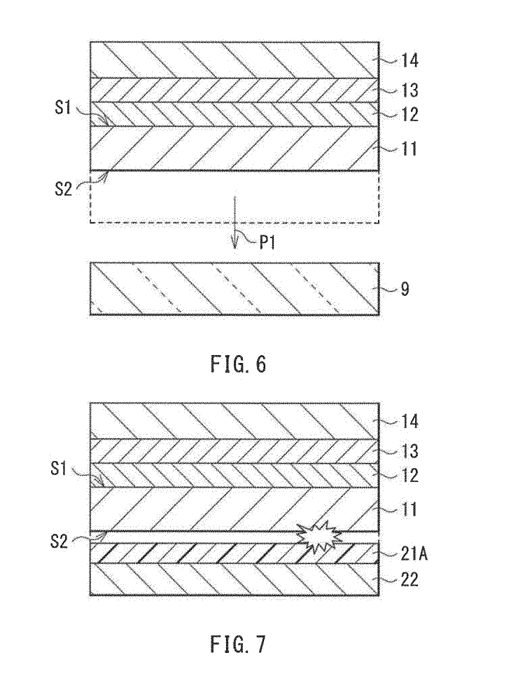

FIGS. 6 and 7 illustrate, in order, a method of manufacturing a display unit according to a comparative example. In the manufacturing method according to the comparative example, an electrically conductive member (the electrically conductive member 21C in FIG. 4) is not formed on the second surface S2 of the flexible substrate 11 upon the detachment of the support substrate 9 from the flexible substrate 11, as illustrated in FIG. 6. For example, when laser light (e.g., the laser light L in FIG. 3) has a small irradiation energy, electrically conductive carbon is hardly generated from the resin material that constitutes the flexible substrate 11.

When the protective member 22 is joined to the flexible substrate 11 including no electrically conductive member, with the adhesive 21A interposed therebetween, static electricity is generated between the flexible substrate 11 and the protective member 22 as illustrated in FIG. 7. This static electricity may possibly influence characteristics of the thin film transistor of the TFT layer 12, thus leading to instability of characteristics of the TFT layer 12. For example, this static electricity may possibly cause shifting of characteristics of a threshold voltage Vth of the thin film transistor, thus leading to dispersion of characteristics of the threshold voltages Vth of a plurality of thin film transistors.

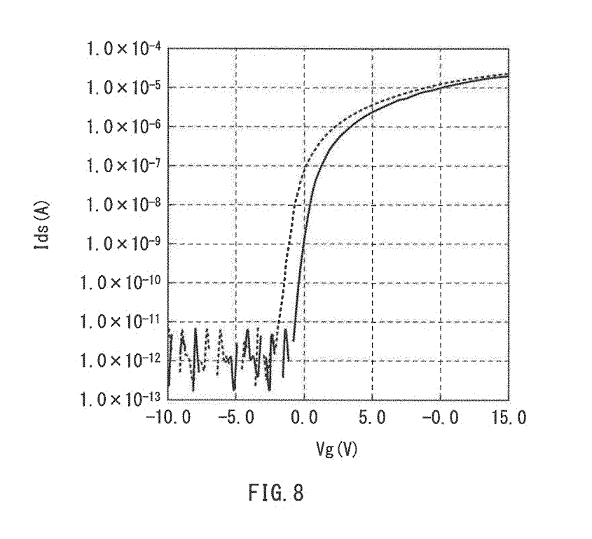

FIG. 8 illustrates variation in the characteristics of the threshold voltage Vth of the thin film transistor. FIG. 8 illustrates the characteristics of the threshold voltage Vth before joining of the protective member 22 (as illustrated in FIG. 6) using a solid line, while illustrating the characteristics of the threshold voltage Vth after joining of the protective member 22 (as illustrated in FIG. 7) using a broken line. As illustrated, the joining of the protective member 22 causes the generation of static electricity and shifting of the threshold voltage Vth by about −1.2 V.

### Example Embodiment

In contrast, the display unit 1 includes the electrically conductive member 21C in contact with the second surface S2 of the flexible substrate 11, thus suppressing the generation of static electricity upon the joining of the protective member 22 (as illustrated in FIG. 5). Hence, for example, the variation in the characteristics of the TFT layer 12 such as the characteristics of the threshold voltage Vth is suppressed.

Further, it is conceivable to join, for example, an electrically conductive film or an antistatic film to the second surface S2 of the flexible substrate 11. This joining method, however, results in higher costs due to expense of the material.

However, as described above, the irradiation of the laser light L allows for the detachment of the support substrate 9 from the flexible substrate 11 and the formation of the electrically conductive member 21C, thereby suppressing an increase in the expense of the material. Hence, the variation in the characteristics of the TFT layer 12 is suppressed, while suppressing an increase in the costs.

As described above, the present example embodiment involves providing the electrically conductive member 21C to be in contact with the second surface S2 of the flexible substrate 11, thus making it possible to suppress the variation in the characteristics of the TFT layer 12 caused by static electricity. Hence, it becomes possible to stabilize the characteristics of the TFT layer 12.

Further, the electrically conductive member 21C may be formed by the irradiation of the laser light L used for the detachment of the support substrate 9 from the flexible substrate 11 (as illustrated in FIGS. 3 and 4), thus making it possible to stabilize the characteristics of the TFT layer 12 while suppressing an increase in the costs.

Furthermore, by forming the organic electroluminescent layer, etc. of the display element layer 13 by means of a printing method, the organic electroluminescent layer, etc. is less likely to be detached even when the irradiation energy of the laser light L is increased.

### Application Example

Description is given of an application example of the display unit 1 according to the foregoing example embodiment to an electronic apparatus.

Description is given first of a block configuration example of the display unit 1.

### Block Configuration Example of Display Unit 1

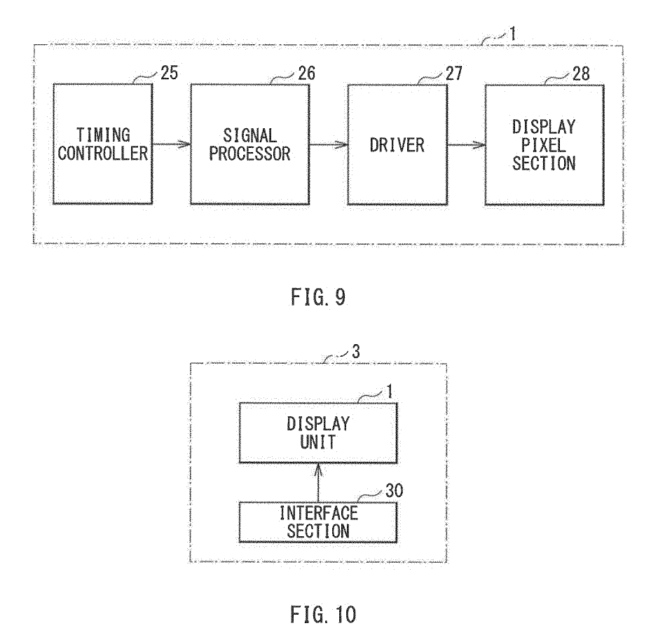

FIG. 9 is a block diagram schematically illustrating an example outline configuration of the display unit 1. The display unit 1 may display an image on the basis of an image signal inputted from an external device or an image signal generated inside. The display unit 1 may be applied not only to the organic EL display as described above but also to a liquid crystal display, for example. The display unit 1 may include, for example, a timing controller 25, a signal processor 26, a driver 27, and a display pixel section 28.

The timing controller 25 may include a timing generator that generates various timing signals (i.e., control signals). On the basis of these various timing signals, the timing controller 25 may perform a drive control of the signal processor 26, for example.

The signal processor 26 may perform, for example, a predetermined compensation on a digital image signal inputted from an external device, and may output the resultant image signal to the driver 27.

The driver 27 may include, for example, a scanning line drive circuit and a signal line drive circuit, and may drive each pixel of the display pixel section 28 through various control lines.

The display pixel section 28 may include, for example, a display element (i.e., the display element layer 13 described above) such as an organic EL element and a liquid crystal display element, and a pixel circuit that drives the display element on a pixel basis. The above-described TFT layer 12 may be used for various circuits that constitute a portion of the driver 27 or the display pixel section 28, for example, among those sections described above.

### Configuration Example of Electronic Apparatus

The display unit 1 described in the foregoing example embodiment may be applied to various types of electronic apparatuses.

FIG. 10 is a block diagram illustrating an example of application to an electronic apparatus (i.e., an electronic apparatus 3) including the display unit illustrated in FIG. 9. Specific but non-limiting examples of the electronic apparatus 3 may include a television, a personal computer (PC), a smartphone, a tablet PC, a mobile phone, a digital still camera, and a digital video camera.

The electronic apparatus 3 may include, for example, the above-described display unit 1 and an interface section 30. The interface section 30 may be an input section that receives various signals and a power supply, for example, from an external device. The interface section 30 may include a user interface such as a touch panel, a keyboard, and operation buttons, for example.

Although description has been given hereinabove of a technique of the disclosure with reference to the example embodiment and the application example, the technology is not limited thereto, but may be modified in a wide variety of ways.

For example, factors such as a material and a thickness of each layer exemplified in the foregoing example embodiment are illustrative and non-limiting. Any other material, any other thickness, and any other factor may be adopted besides those described above. Moreover, it is not necessary for the display unit to include all of the layers described above. In an alternative embodiment, the display unit may further include any other layer in addition to the layers described above.

Moreover, the foregoing example embodiment exemplifies the case where the carbonization of a portion of the flexible substrate 11 allows for formation of the electrically conductive member 21C, as illustrated in FIGS. 3 and 4. However, any other method may be used to form the electrically conductive member 21C. For example, the electrically conductive member 21C may be mixed into the adhesive 21A.

Note that the effects described herein are mere examples. The effect of the disclosure is not limited thereto, and may include other effects.

Note that the technology may also have the following configurations.
(1)

A display unit including:

a flexible substrate including a first surface and a second surface that face each other;

a thin film transistor layer provided over the first surface of the flexible substrate;

a display element layer including a light-emitting layer, and being provided over the first surface of the flexible substrate, with the thin film transistor layer interposed between the display element and the flexible substrate;

an electrically conductive member provided to be in contact with the second surface of the flexible substrate; and

a protective member facing the second surface of the flexible substrate, with the electrically conductive member interposed between the protective member and the flexible substrate.
(2)

The display unit according to (1), in which the electrically conductive member is carbon.
(3)

The display unit according to or (2), in which the flexible substrate includes a resin material.
(4)

The display unit according to any one of (1) to (3), further including an adhesive layer provided between the flexible substrate and the protective member, and including the electrically conductive member.
(5)

The display unit according to (4), in which a resistance value of a facing surface of the adhesive layer, with respect to the flexible substrate is 10⁵ Ω/sq or lower.
(6)

The display unit according to any one of (1) to (5), in which the light-emitting layer includes an organic light-emitting material.
(7)

A method of manufacturing a display unit, the method including:

joining a support substrate to a second surface of a flexible substrate including a first surface and the second surface that face each other;

forming a thin film transistor layer over the first surface of the flexible substrate;

forming, over the thin film transistor layer, a display element layer including a light-emitting layer;

detaching the support substrate from the second surface of the flexible substrate, and forming an electrically conductive member that is in contact with the second surface of the flexible substrate; and

joining a protective member to the second surface of the flexible substrate, with the electrically conductive member interposed between the protective member and the flexible substrate.
(8)

The method of manufacturing the display unit according to (7), in which the detachment of the support substrate from the second surface of the flexible substrate involves irradiation of laser light.
(9)

The method of manufacturing the display unit according to (8), in which the laser light has irradiation energy 1.15 times or higher than energy necessary for the detachment of the support substrate.
(10)

The method of manufacturing the display unit according to (8) or (9), in which the irradiation of the laser light carbonizes a portion of the flexible substrate to form the electrically conductive member.
(11)

The method of manufacturing the display unit according to any one of (7) to (10), in which the light-emitting layer is formed by a printing method.

The display unit according to one embodiment of the technology includes the electrically conductive member in contact with the second surface of the flexible substrate. Thus, for example, it is possible to suppress generation of static electricity upon joining the protective member to the second surface of the flexible substrate.

The method of manufacturing the display unit according to one embodiment of the technology includes forming the electrically conductive member that is in contact with the second surface of the flexible substrate. Thus, it is possible to suppress the generation of static electricity upon joining the protective member to the second surface of the flexible substrate.

According to the display unit of one embodiment of the technology, the electrically conductive member is provided to be in contact with the second surface of the flexible substrate. Further, according to the method of manufacturing the display unit of one embodiment of the technology, the electrically conductive member in contact with the second surface of the flexible substrate is formed. Thus, it is possible to suppress variation characteristics of the thin film transistor layer caused by static electricity. Hence, it becomes possible to stabilize the characteristics of the thin film transistor layer.

Note that the effects described herein are not necessarily limitative, and may be any of the effects described in the disclosure.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this technology, the term “preferably” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” as used herein can allow for a degree of variability in a value or range. Moreover, no element or component in this technology is intended to be dedicated to the public regardless of whether the element or component is explicitly recited in the following claims.

What is claimed is:

1. A display unit comprising:
a flexible substrate including a first surface and a second surface that face each other;
a thin film transistor layer provided over the first surface of the flexible substrate;
a display element layer including a light-emitting layer, and being provided over the first surface of the flexible substrate, with the thin film transistor layer interposed between the display element and the flexible substrate;
an electrically conductive member provided to be in contact with the second surface of the flexible substrate; and
a protective member facing the second surface of the flexible substrate, with the electrically conductive member interposed between the protective member and the flexible substrate.

2. The display unit according to claim 1, wherein the electrically conductive member comprises carbon.

3. The display unit according to claim 1, wherein the flexible substrate includes a. resin material.

4. The display unit according to claim 1, further comprising an adhesive layer provided between the flexible substrate and the protective member, and including the electrically conductive member.

5. The display unit according to claim 4, wherein a resistance value of a facing surface of the adhesive layer, with respect to the flexible substrate is 10⁵ Ω/sq or lower.

6. The display unit according to claim 1, wherein the light-emitting layer includes an organic light-emitting material.

7. A method of manufacturing a display unit, the method comprising:
joining a support substrate to a second surface of a flexible substrate including a first surface and the second surface that face each other;
forming a thin film transistor layer over the first surface of the flexible substrate;
forming, over the thin film transistor layer, a display element layer including a light-emitting layer;
detaching the support substrate from the second surface of the flexible substrate, and forming an electrically conductive member that is in contact with the second surface of the flexible substrate; and
joining a protective member to the second surface of the flexible substrate, with the electrically conductive member interposed between the protective member and the flexible substrate.

8. The method of manufacturing the display unit according to claim 7, wherein the detachment of the support substrate from the second surface of the flexible substrate involves irradiation of laser light.

9. The method of manufacturing the display unit according to claim 8, wherein the laser light has irradiation energy 1.15 times or higher than energy necessary for the detachment of the support substrate.

10. The method of manufacturing the display unit according to claim 8, wherein the irradiation of the laser light carbonizes a portion of the flexible substrate to form the electrically conductive member.

11. The method of manufacturing the display unit according to claim 7, wherein the light-emitting layer is formed by a printing method.
